(19) United States
(12) Patent Application Publication
(10) Pub. No.: US 2007/0170572 A1
(43) Pub. Date: Jul. 26, 2007

(54) Multichip stack structure

(75) Inventors: Kun-Chen Liu, Taichung (TW); Chien-Chih Chen, Taichung (TW); Chung-Pao Wang, Taichung (TW)

Correspondence Address: EDWARDS ANGELL PALMER & DODGE LLP, P.O. BOX 55874, BOSTON, MA, 02205, US

(73) Assignee: Siliconware precision industries Co., Ltd., Taichung (TW)

(21) Appl. No.: 11/591,973

(22) Filed: Nov. 1, 2006

(30) Foreign Application Priority Data
Jan. 26, 2006 (TW) 095103006

(51) Int. Cl. H01L 23/02

(52) U.S. Cl. 257/686; 257/E23.085

(57) ABSTRACT

A multi-chip stack structure includes a chip carrier, a plurality of chips stacked stepwise on the chip carrier, and a passive component disposed on the chip carrier. The passive component is located under the stepwise chips that are cantilevered over it. Therefore, the passive component serves as a block element or a filling element in the molding process, and problems such as chip peeling void are prevented. Meanwhile, the electrical properties of the package are improved.

### FIELD OF THE INVENTION

This invention relates to multi-chip stack structures, and more particularly, to a multi-chip stack structure having a plurality of chips with bond pads provided only on one side of the chips.

### BACKGROUND OF THE INVENTION

One way to produce increasingly complex electronic components is to include a greater number of IC chips on a substrate, e.g. a memory card. However, such chips can take up a lot of substrate surface area. One solution to this dilemma is to form a stack of chips on a substrate, creating what is known in the art as a multi-chip package.

The demand for miniaturization of electronic products with high-speed operation often necessitates utilizing packages that incorporate two or more semiconductor chips in one single package structure, thereby reducing the overall size while increasing the functionality and/or electrical performance of the package. Moreover, a multi-chip structure generally has the least limitation on system operational speed by stacking a plurality of chips because a stacked multi-chip structure can reduce the length of the connecting wires between chips to reduce signal delays and access times.

The often-seen multi-chip package structures typically adopt a top-to-bottom configuration, i.e. by stacking two or more chips on a major installation surface of a common substrate. However, this top-to-bottom multi-chip configuration has some distinct disadvantages in that it takes up a relatively large amount of space within the package as well as on the common substrate due to the increased number of chips.

To overcome the problems of the prior art as mentioned above, a common method used in recent years is to stack the multiple chips in varied ways according to the chip design and the wire bonding process. For example, a memory card structure is a circuit module incorporating a plurality of high-capacity chips, in which the flash memory chips thereof are formed by configuring bond pads on the surface of only one side of the chip, such that the chips can be stacked in a stepwise fashion, thereby allowing the stacked chips to expose the bond pads configured on one side for a subsequent wire bonding process.

Referring to FIG. 1, a stacked multiple offset chip device disclosed by U.S. Pat. No. 6,900,528 is illustrated, characterized in that a plurality of chips is stacked on a chip carrier 10, wherein a first chip 11 is mounted on the chip carrier 10, and a second chip 12 is stacked on the first chip 11 at an offset distance so as not to interfere with the wire bonding process for the bond pads 110 of the first chip 12, thus forming a stepwise multi-chip stack structure. Then, a third chip 13 is similarly mounted on the second chip 12. Subsequently, a wire-bonding process is performed to electrically connect the first, second, and third chips 11, 12, 13 to said chip carrier by means of a plurality of bond wires 14.

The aforementioned step-like multi-chip stacked structure can save more space than aligning the chips, and the wire bonding process can be performed after stacking the chips, and further, an encapsulant can be formed by a molding process for encapsulating the stacked chips and bond wires, such a design being able to speed up the fabrication process. However, some potential problems may arise because of the sweep or breakage of bond wires in the molding process due to the impact of mold flow. The position of the mold gate in a molding process has to be parallel with the arcs of the bond wires, as depicted in FIGS. 2A and 2B, in which the bond wires are either arranged to be away from the mold gate G, as shown in FIG. 2A, or, conversely, towards the mold gate G as shown in FIG. 2B.

However, referring to FIG. 2A, when the bond wires are away from the mold gate G through which a resin material is injected in the molding process to form an encapsulant for encapsulating the step-like multi-chip stacked structure, the resin mold flow directly strikes against the underside of the cantilevered portion of the upper-layer chip in said step-like multi-chip stacked structure, which tends to cause delaminating of the upper-layer chip (as shown by dotted lines).

Conversely, as shown in FIG. 2B, when the bond wires face towards the mold gate G during the molding process and resin material is injected into the mold gate G to form an encapsulant for encapsulating the stacked structure, formation of voids under the cantilevered portion of the upper-layer chip in said step-like multi-chip stacked structure may occur due to the reflow of mold flow and may even lead to the problem of the popcorn effect in the subsequent heating process or reliability testing, adversely effecting the quality of the packaged products as a result.

Referring to FIG. 3, a planar view of a semiconductor device disclosed by U.S. Pat. No. 6,040,622 is shown, in which a plurality of passive elements 35 such as capacitors, resistors or inductors are added to the package structure to enhance the electrical performance of an electronic product such as the memory card described earlier, and the passive elements 35 are typically configured on both sides of the chip 31, undesirably increasing the profile size of the packaged structure.

Therefore, it is desirable to provide an improved type of multi-chip semiconductor device that can prevent the formation of voids and delamination in the molding process, and also provide an effective area for attaching passive elements thereon, thereby allowing for increased functionality or performance while reducing package size.

### SUMMARY OF THE INVENTION

In view of the drawbacks of the prior art, an objective of the invention is to provide a multi-chip stack structure that can prevent the problem of delamination caused by the impact of mold flow in a molding process.

Another objective of the invention is to provide a multi-chip stack structure that can effectively prevent the formation of voids in a molding process.

Another objective of the invention is to provide a multi-chip stack structure that can provide an effective attachment area for mounting passive components.

To achieve the above and other objectives, the present invention provides a multi-chip stack structure, comprising: a chip carrier; a plurality of semiconductor chips stacked stepwise one on another in vertical configuration on said chip carrier; and one or more passive components disposed on said chip carrier located at a position under the stepwise stacked chips where they cantilever over the substrate. The semiconductor chips are constituted to have only single-side bond pads mounted thereon that are stacked stepwise on said chip carrier without interfering with the subsequent wire-bonding process, thereby allowing the semiconductor chips to be electrically connected to said chip carrier via a plurality of bond wires.

The multi-chip stack structure according to the invention is characterized by its configuration of a multi-chip stepwise stacked structure, in which one or more passive components are disposed on the chip carrier prior to chip stacking on the side where the stacked chips will cantilever above the substrate, such that in the molding process, the passive components can serve as filling elements when the arcs of the bond wires are parallel to the mold gate, thus helping to prevent the formation of voids. Conversely, when the bond wires are away from the mold gate, the passive components can serve as blocking elements to help prevent the mold flow from directly striking against the stacked chips, leading to chip peelings and delamination. Further, this configuration, regardless of the orientation of the bond wires with respect to the mold flow direction, reduces the dimensions of the packaging structure by locating passive components in the otherwise unused space under the cantilevered portion of the stacked chips.

### BRIEF DESCRIPTION OF THE DRAWINGS

The multi-chip stack structure of the present invention can be more fully understood by reading the following detailed description of the preferred embodiments, with reference made to the accompanying drawings, wherein:

FIG. 1 (PRIOR ART) is a sectional view showing a multi-chip stack structure disclosed by U.S. Pat. No. 6,900,528;

FIG. 2A (PRIOR ART) is a sectional view of a conventional multi-chip stack structure encountering the problem of an upper-layer chip peeling away due to pressure applied during a molding process;

FIG. 2B (PRIOR ART) is a sectional view of a conventional multi-chip stack structure encountering the problem of gas bubbles in a molding process;

FIG. 3 (PRIOR ART) is a planar view showing a semiconductor device disclosed by U.S. Pat. No. 6,040,622;

FIGS. 4A and 4B are, respectively, a sectional and a planar view showing a first preferred embodiment of the multi-chip stack structure according to the present invention; and

FIG. 5 is a sectional view showing a second preferred embodiment of the multi-chip stack structure according to the present invention.

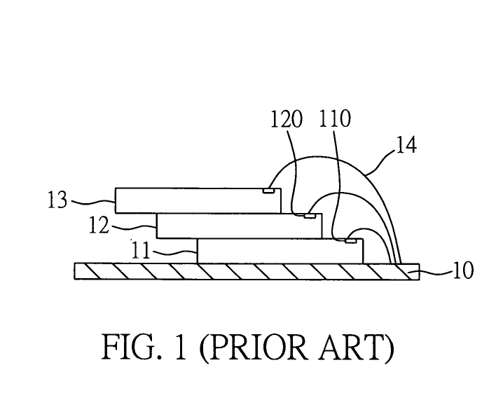

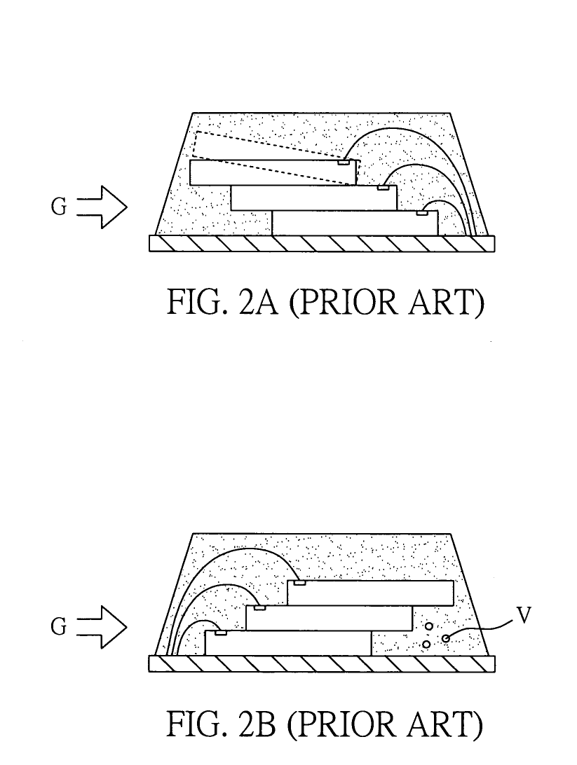

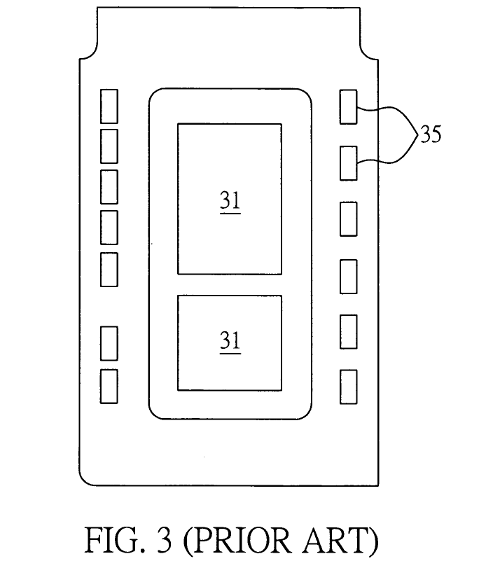

### DESCRIPTION OF THE PREFERRED EMBODIMENTS

The present invention is described in the following so that one skilled in the pertinent art can easily understand other advantages and effects of the present invention. The present invention may also be implemented and applied according to other embodiments, and the details may be modified based on different views and applications without departing from the spirit of the invention.

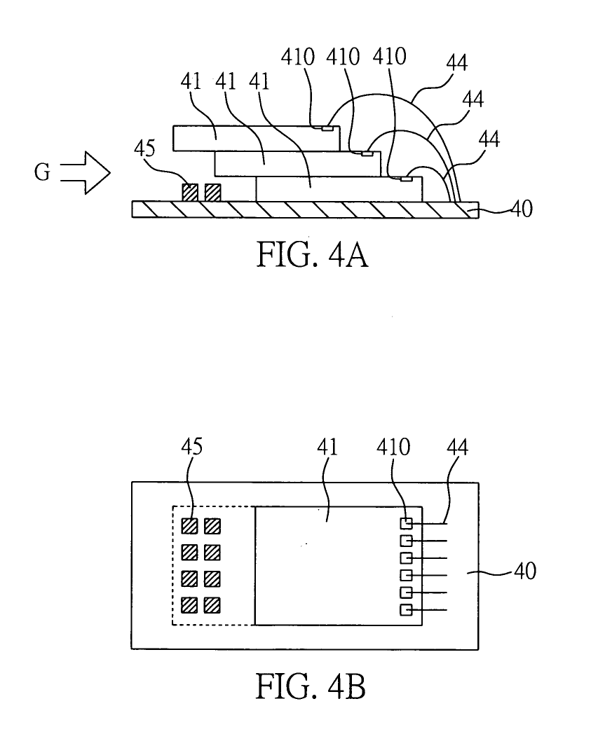

FIG. 4A illustrates a sectional view and FIG. 4B a planar view showing the multi-chip stack structure according to the invention. As shown, said multi-chip stack structure is comprised of: a chip carrier 40; a plurality of semiconductor chips 41 stacked stepwise one on another in a vertical configuration on said chip carrier 40; and one or more passive components 45 disposed on said chip carrier 40 located at the position where the stepwise stacked chips cantilever over the substrate.

Said chip carrier 40 can be a substrate structure, and the plurality of semiconductor chips 41 to be stacked stepwise can be flash memory chips having substantially identical or similar dimensions, wherein on one side thereof is provided a plurality of bond pads 410 at a predetermined distance between an upper-layer semiconductor chip 41 and a lower-layer semiconductor chip 41 by using only one side thereof for bond pads 410, the same side of each chip, such that an upper-layer semiconductor chip 41 will not block the pads of a lower-layer semiconductor chip 41 due to stepwise stacking, thereby facilitating the stepwise chip-stacked configuration so that the bond pads 410 of each semiconductor chip 41 are exposed to provide electrical connection with said chip carrier 40 via a plurality of bond wires 44.

In this embodiment, the layout arrangement of bond wires 44 is parallel with the mold gate G for injecting the resin material for packaging the multi-chip stack structure, and the bond wires are located at one side away from the mold gate, i.e. the cantilevered chip portion of said stepwise stack structure is facing toward the side of said mold gate G.

Passive components 45, such as capacitors, resistors or inductors, can be disposed on the chip carrier 40 at the position under the stacked chips that cantilever above the chip carrier 40, which can increase the overall electrical performance and also the passive components 45 can serve as blocking elements to reduce the impact of the resin flow directly on the stepwise stack structure that may cause chip peeling or delamination as a result of applied pressure.

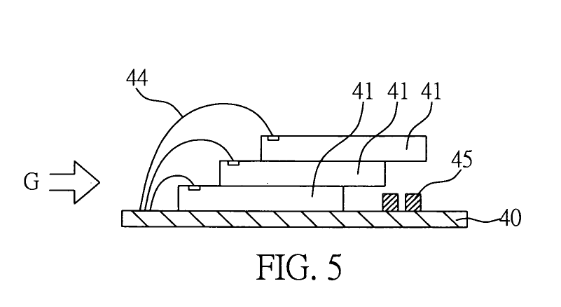

FIG. 5 is a sectional view showing a second preferred embodiment of the multi-chip stack structure according to the present invention. The construction of the multi-chip stack structure of this embodiment is substantially the same as the first embodiment and only differs in that the bond wires are disposed towards the side of the mold gate G, i.e. the cantilevered chip portion of said stepwise stack structure is away from the side of said mold gate G, such that the passive component 45 disposed on the chip carrier 40 and located under the stepwise stacked chips cantilevered above the substrate can be used as filling elements to prevent gas bubbles or the formation of voids in the molding process.

In summary, the multi-chip stack structure according to the invention is characterized by stacking multiple chips in a stepwise configuration, and also disposing at least one passive component at the position where the stacked chips cantilever above the substrate, such that in the molding process, the passive components can serve as a filling element when the bond wires are parallel to the mold gate to thereby prevent the formation of voids. Conversely, when the bond wires are away from the mold gate, the passive components can serve as blocking elements to prevent the mold flow from directly striking against the stacked chips, which might otherwise lead to chip peelings and delamination. Moreover, at the same time, the design allows the electrical properties of the package to be improved as a result.

It should be apparent to those skilled in the art that the above description is only illustrative of specific embodiments and examples of the present invention. The present invention should therefore cover various modifications and variations made to the herein-described structure and operations of the present invention, provided that they fall within the scope of the present invention as defined in the following appended claims.

What is claimed is:

1. A multi-chip stack structure, comprising:
a chip carrier;
a plurality of semiconductor chips stacked stepwise one on another in vertical configuration on said chip carrier; and
one or more passive components disposed on said chip carrier located at the position under the stepwise stacked chips that are cantilevered above the substrate.

2. The multi-chip stack structure according to claim 1, wherein the chip carrier is a substrate.

3. The multi-chip stack structure according to claim 1, wherein the semiconductor chip is a flash memory chip.

4. The multi-chip stack structure according to claim 1, wherein the semiconductor chips are fabricated with bond pads on only one side mounted thereon that are stacked in order stepwise on said chip carrier, thus exposing the bond pads and forming a stepwise stack-chip structure with chips cantilevered on one side.

5. The multi-chip stack structure according to claim 1, wherein the bond pads of the semiconductor chips are disposed on the same side, and each succeeding stacked layer is configured to deviate from the layer beneath it by a predetermined distance, so as to avoid blocking the bond pads of the lower layers of the stepwise vertical stack, thereby exposing the bond pads to allow the plurality of semiconductor chips to be electrically connected to the chip carrier via bond wires.

6. The multi-chip stack structure according to claim 1, wherein the semiconductor chips electrically connect to the chip carrier via a plurality of solder wires.

7. The multi-chip stack structure according to claim 6, wherein the layout direction of the solder wires is parallel to the mold gate adapted for injecting packaging resin thereto for packaging the multi-chip stack structure.

8. The multi-chip stack structure according to claim 7, wherein the ends of the solder wires are disposed on one side away from the mold gate.

9. The multi-chip stack structure according to claim 7, wherein the cantilevered portion of the stepwise-stacked chips is disposed on one side towards the mold gate.

10. The multi-chip stack structure according to claim 7, wherein the ends of the solder wires are disposed on one side towards the mold gate.
